(19) United States
(12) Patent Application Publication
(10) Pub. No.: US 2013/0292839 A1
(43) Pub. Date: Nov. 7, 2013

(54) POROUS SILICON MATERIAL

(71) Applicants: Kazuhiro Fukami, Uji-shi (JP); Yukio Ogata, Uji-shi (JP); Tetsuo Sakka, Uji-shi (JP); Ryo Koda, Uji-shi (JP); Tomoko Urata, Uji-shi (JP)

(72) Inventors: Kazuhiro Fukami, Uji-shi (JP); Yukio Ogata, Uji-shi (JP); Tetsuo Sakka, Uji-shi (JP); Ryo Koda, Uji-shi (JP); Tomoko Urata, Uji-shi (JP)

(73) Assignee: KYOTO UNIVERSITY, Kyoto-shi, Kyoto (JP)

(21) Appl. No.: 13/990,889

(22) PCT Filed: Nov. 7, 2011
(86) PCT No.: PCT/JP2011/075586

§ 371 Date: Jul. 1, 2013

(30) Foreign Application Priority Data
Dec. 1, 2010 (JP) 2010-268018
Feb. 8, 2011 (JP) 2011-024579

(51) Int. Cl. H01L 21/768; H01L 23/498

(52) U.S. Cl. CPC H01L 21/76879; H01L 23/498
USPC 257/773; 438/675

(57) ABSTRACT

Provided are a method for producing a porous silicon material filled with a metal, the method including the steps of rendering hydrophobic a porous silicon substrate having pores from 1 to 5 nm in diameter, and depositing a metal into the pores of the porous silicon substrate by the electrodeposition of the porous silicon substrate; a method for producing a metallic nanoparticle or a nanofiber, the method including the steps of producing a porous silicon material filled with a metal, dissolving the silicon contained in the porous silicon material filled with a metal; a metallic nanoparticle or a nanofiber obtained by using the method for producing a metallic nanoparticle or a nanofiber: and a porous silicon material formed from a porous silicon substrate having pores from 1 to 5 nm in diameter and a resistivity of 5 to 20 Ω·cm, the pores of which are filled with a metal.

### TECHNICAL FIELD

The present invention relates to a porous silicon material. More specifically, the present invention relates to a porous silicon material and a method for producing the same, and a method for producing metallic nanoparticles or nanofibers by using the method for producing a porous silicon material. The porous silicon material of the present invention is useful for an electrode for a wet solar cell, an electrode for a fuel cell and the like. Also, metallic nanoparticles or nanofibers are useful as an electrode material for a fuel cell or the like, a catalytic material, a biosensing material and the like because they have a high specific surface area.

In the present description, metallic nanoparticles or nanofibers are collective designation for metallic particles and metallic fibers having a diameter in the order of nanometer, for example, a diameter of about 1 to about 5 nm. The metallic nanoparticles or nanofibers conceptually involve metallic particles alone, metallic fibers alone, and mixture of metallic particles and metallic fibers. Also, a porous silicon substrate filled with a metal means a porous silicon substrate having pores filled with a metal.

### BACKGROUND ART

A silicon material including a porous silicon substrate of which pores are filled with a metal is one of the materials that have been recently focused because of its usefulness for an electrode for a wet solar cell, an electrode for a fuel cell and the like.

As a method for producing a metal-carrying porous silicon having a large pore diameter and a high porosity of a porous layer, there has been proposed a method for producing a metal-carrying porous silicon wherein the amount of metal ions contained in a deposition liquid is adjusted to a predetermined value when a silicon substrate having a porous layer is clipped in the deposition liquid, and a silicon oxide film formed on the porous layer is dissolved, and a metal is precipitated (see, for example, Patent Document 1).

However, in this method for producing a metal-carrying porous silicon, when a silicon substrate having a porous layer having a large pore diameter of about 20 to about 50 nm is used, a metal-carrying porous silicon can be produced, however, when a silicon substrate having a very small pore diameter of about 1 to about 5 nm is used, pores existing in the surface of the porous layer are clogged by a precipitated metal when the metal is precipitated by using a deposition liquid, and disadvantageously the pores cannot be sufficiently filled with the metal. Furthermore, since a metal-carrying porous silicon obtained by the foregoing producing method has a large pore diameter of the porous layer, the mechanical strength itself is not so high.

Therefore, in recent years, it has been desired to develop a method for producing a porous silicon material having pores filled with a metal, the method being capable of sufficiently filling pores of a porous silicon substrate having a very small pore diameter of about 1 to about 5 nm with a metal.

### PRIOR ART DOCUMENTS

### Patent Documents

Patent Document 1: Japanese Unexamined Patent Publication No. 2007-119897

### DISCLOSURE OF THE INVENTION

### Problems to be Solved by the Invention

The present invention has been accomplished in light of the foregoing conventional arts. An object of the present invention is to provide a method for producing a porous silicon material capable of filling the pores of a porous silicon substrate having a very small pore diameter of about 1 to about 5 nm with a metal, and a porous silicon material having pores of about 1 to about 5 nm in pore diameter filled with a metal. Another object of the present invention is to provide a method capable of producing metallic nanoparticles or metallic nanofibers by using the aforementioned method for producing a porous silicon material.

### Means for Solving the Problems

The present invention relates to:

(1) a method for producing a porous silicon material filled with a metal, the method which includes carrying out a hydrophobizing treatment on a porous silicon substrate having pores of 1 to 5 nm in pore diameter, and then carrying out an electrodeposition treatment on the porous silicon substrate to precipitate metal inside the pores of the porous silicon substrate;
(2) the method for producing a porous silicon material according to the above (1), wherein the porous silicon substrate having pores of 1 to 5 nm in pore diameter is produced by forming pores in a silicon substrate having a specific resistance of 5 to 20 Ω·cm with the use of hydrogen fluoride;
(3) the method for producing a porous silicon material according to the above (1) or (2), wherein the hydrophobizing treatment is carried out on the porous silicon substrate by using an organic compound having a carbon-carbon unsaturated double bond or a carbon-carbon unsaturated triple bond, and a hydrophobic group at its terminal;
(4) a method for producing metallic nanoparticles or nanofibers, the method including producing a porous silicon material filled with a metal by the method for producing a porous silicon material according to any one of the above (1) to (3), and then dissolving silicon contained in the porous silicon material filled with a metal;
(5) metallic nanoparticles or nanofibers obtained by the producing method according to the above (4);
(6) a porous silicon material, wherein pores of a porous silicon substrate having pores of 1 to 5 nm in pore diameter, and a specific resistance of 5 to 20 Ω·cm are filled with a metal; and
(7) the porous silicon material according to the above (6), which is a porous silicon material obtained by the method for producing according to any one of the above (1) to (3).

### Effects of the Invention

According to the method for producing a porous silicon material of the present invention, such an excellent effect is achieved that a porous silicon material in which the pores of a porous silicon substrate having a very small pore diameter of about 1 to about 5 nm are filled with a metal can be produced. The porous silicon material of the present invention advantageously has excellent mechanical strength because the pores of a porous silicon substrate having a very small pore diameter of about 1 to about 5 nm are filled with a metal. Also, according to the method for producing metallic nanoparticles or metallic nanofibers of the present invention, metallic nanoparticles or metallic nanofibers having a very small pore diameter of about 1 to about 5 nm are obtained, and the metallic nanoparticles or metallic nanofibers are expected to be used in various applications such as a metal catalyst owing to their light weight.

### BRIEF DESCRIPTION OF DRAWINGS

FIG. 1 is a substitute photograph for a drawing showing an image of the cross section of the porous silicon substrate obtained in Example 3 taken under a scanning electron microscope.

FIG. 2 is a substitute photograph for a drawing of an image showing the distribution of silicon atoms in a cross section of the porous silicon substrate obtained in Example 3 taken under energy dispersive X-ray.

FIG. 3 is a substitute photograph for a drawing of an image showing the distribution of platinum atoms in a cross section of the porous silicon substrate obtained in Example 3 taken under energy dispersive X-ray.

FIG. 4 is a substitute photograph for a drawing of an image showing the distribution of carbon atoms in a cross section of the porous silicon substrate obtained in Example 3 taken under energy dispersive X-ray.

FIG. 5 is a substitute photograph for a drawing of an image showing the distribution of oxygen atoms in a cross section of the porous silicon substrate obtained in Example 3 taken under energy dispersive X-ray.

FIG. 6 is a substitute photograph for a drawing showing an image of a cross section of the porous silicon substrate obtained in Comparative Example 3 taken under a scanning electron microscope.

FIG. 7 is a substitute photograph for a drawing of an image showing the distribution of silicon atoms in a cross section of the porous silicon substrate obtained in Comparative Example 3 taken under energy dispersive X-ray.

FIG. 8 is a substitute photograph for a drawing of an image showing the distribution of platinum atoms in a cross section of the porous silicon substrate obtained in Comparative Example 3 taken under energy dispersive X-ray.

FIG. 9 is a substitute photograph for a drawing of an image showing the distribution of carbon atoms in a cross section of the porous silicon substrate obtained in Comparative Example 3 taken under energy dispersive X-ray.

FIG. 10 is a substitute photograph for a drawing of an image showing the distribution of oxygen atoms in a cross section of the porous silicon substrate obtained in Comparative Example 3 taken under energy dispersive X-ray.

FIG. 11 is a view showing the result obtained in Example 4, by carrying out an electrodeposition treatment on a porous silicon material in which a porous layer is dissolved, and scraping off the porous layer where platinum precipitates, and observing the porous layer that is scraped off by Fourier transform infrared spectroscopy.

FIG. 12 is a view showing the result obtained in Example 4, by scraping off a porous layer of a porous silicon material in which the porous layer is dissolved, and observing the porous layer that is scraped off by Fourier transform infrared spectroscopy.

FIG. 13 is a view showing the result obtained in Comparative Example 4, by carrying out an electrodeposition treatment on a porous silicon material in which a porous layer is dissolved, and scraping off the porous layer where platinum precipitates, and observing the porous layer that is scraped off by Fourier transform infrared spectroscopy.

FIG. 14 is a view showing the result obtained in Comparative Example 4, by scraping off a porous layer of a porous silicon material in which the porous layer is dissolved, and observing the porous layer that is scraped off by Fourier transform infrared spectroscopy.

FIG. 15 is a view showing the measurement result of infrared absorption after carrying out a hydrolysis treatment on the porous silicon substrate, to which a hydrophobizing treatment has been conducted, obtained in Example 5.

FIG. 16 is a substitute photograph for a drawing showing the measurement result of contact angle of water drop in Example 6, with respect to the porous silicon substrate, to which a hydrophobizing treatment has been conducted, obtained in Example 1 and with respect to the porous silicon substrate to which a hydrophilizing treatment has been conducted, obtained in Comparative Example 2.

FIG. 17 is a transmission electron photograph of the sample obtained in Example 7.

FIG. 18 is a transmission electron photograph of the sample obtained in Example 7.

FIG. 19 is a view showing the measurement result of energy dispersive X-ray analysis in Example 8 in the site where platinum particles are present in the porous silicon substrate, to which a hydrophobizing treatment has been conducted, obtained in Example 1.

FIG. 20 is a view showing the measurement result of energy dispersive X-ray analysis in Example 8 in the site where platinum particles are absent in the porous silicon substrate, to which a hydrophobizing treatment has been conducted, obtained in Example 1.

FIG. 21 is a drawing photograph showing the measurement result of contact angle of the porous silicon substrate, to which a hydrophobizing treatment has been conducted, obtained in Example 1 against water in Example 10.

FIG. 22 is a drawing photograph showing the measurement result of contact angle of the porous silicon substrate, to which a hydrophobizing treatment has been conducted, obtained in Comparative Example 2 against water in Example 10.

FIG. 23 is a scanning electron photograph of a cross section of the porous silicon material after carrying out platinum deposition on the porous silicon substrate, to which a hydrophobizing treatment has been conducted, obtained in Example 1, in Example 11.

FIG. 24 is a scanning electron photograph of a cross section of the porous silicon material after carrying out platinum deposition on the porous silicon substrate, to which a hydrophobizing treatment has been conducted, obtained in Comparative Example 2, in Example 11.

FIG. 25 is a substitute photograph for a drawing of an image in a cross section of the porous silicon substrate obtained in Example 12 taken under a transmission electron microscope.

FIG. 26 is a substitute photograph for a drawing of an image in a cross section of the porous silicon substrate obtained in Example 13 taken under a transmission electron microscope.

FIG. 27 is a substitute photograph for a drawing of an image in a cross section of the porous silicon substrate obtained in Example 14 taken under a scanning electron microscope.

FIG. 28 is a substitute photograph for a drawing of an image in a cross section of the porous silicon substrate obtained in Comparative Example 4 taken under a scanning electron microscope.

FIG. 29 is a substitute photograph for a drawing of an image in a cross section of the porous silicon substrate obtained in Example 15 taken under a scanning electron microscope.

### MODES FOR CARRYING OUT THE INVENTION

As described above, the method for producing a porous silicon material of the present invention is characterized by carrying out a hydrophobizing treatment on a porous silicon substrate having pores of 1 to 5 nm in pore diameter, and then carrying out an electrodeposition treatment on the porous silicon substrate to precipitate metal inside the pores of the porous silicon substrate.

The porous silicon substrate having pores of 1 to 5 nm in pore diameter can be produced by using a silicon substrate having a specific resistance of 5 to 20 Ω·cm as a silicon substrate. One of major characteristics of the present invention resides in that a silicon substrate having a specific resistance of 5 to 20 Ω·cm is used as a silicon substrate. According to the present invention, since a silicon substrate having a specific resistance of 5 to 20 Ω·cm is used, it is possible to readily form pores having a pore diameter of 1 to 5 nm in the silicon substrate. The silicon which forms a silicon substrate may be any one of monocrystalline silicon and polycrystalline silicon.

Examples of a method for forming pores having a pore diameter of 1 to 5 nm in the silicon substrate include an anode oxidization method by electrolysis and the like, and the present invention is not limited only to the methods. In the anode oxidization method by electrolysis, the electrolyte is preferably a solution of hydrogen fluoride in lower alcohol containing hydrogen fluoride in a concentration of 10 to 25% by weight from the viewpoint of forming a large number of pores having even pore diameters in the silicon substrate. Examples of the lower alcohol include monohydric alcohols having 1 to 4 carbon atoms such as methanol, ethanol, n-propanol, isopropanol and n-butanol. Among these lower alcohols, ethanol is preferred from the viewpoint of forming a large number of pores having even pore diameters in the silicon substrate.

The size of the silicon substrate cannot be absolutely determined because it differs depending on the uses of the porous silicon material filled with a metal of the present invention. For example, when the porous silicon material filled with a metal of the present invention is used as an electrode for a wet solar cell, the longitudinal length may be about 5 to about 20 mm, the lateral length may be about 5 to about 20 mm, and the thickness of the porous layer may be about 3 to about 10 μm.

When a porous silicon material is produced from a silicon substrate through the anode oxidation method by electrolysis, the porous silicon material can be produced by applying a current under the condition such that the silicon substrate is in contact with an electrolyte to function as a cathode, and an anode made of platinum or the like is in contact with the electrolyte. At this time, the liquid temperature of the electrolyte is not particularly limited, and usually may be room temperature. The current density at the time of applying a current to the electrolyte is preferably 0.5 to 5 mA/cm², and more preferably 1 to 3 mA/cm² from the viewpoint of producing a porous silicon substrate having pores of 1 to 5 nm in pore diameter.

The pore diameter of pores formed in the porous silicon substrate is 1 nm or more, and preferably 2 nm or more from the viewpoint of facilitating control of metal precipitation as will be described later, and is 5 nm or less, and preferably 3 nm or less from the viewpoint of producing metallic nanop articles or nanofibers having a desired specific surface area. The pore diameter of pores formed in the porous silicon substrate means a diameter of pores formed in the porous silicon substrate. The pore diameter of pores formed in the porous silicon substrate is, for example, a value observed by using a transmission electron microscope or a scanning electron microscope. Also, the porosity of the porous silicon substrate is preferably about 70 to about 95% from the viewpoint of the increase of the specific surface area and the mechanical strength.

Next, a hydrophobizing treatment is carried out on the porous silicon substrate. Another characteristic of the present invention resides in that a hydrophobizing treatment is carried out on the porous silicon substrate.

The present inventors have attempted to produce porous silicon having pores filled with a metal by carrying out an electrodeposition treatment on a porous silicon substrate, and found out that a porous silicon substrate filled with a metal cannot be obtained when a porous silicon substrate having a pore diameter of less than 10 nm is used. Thus, the present inventors have earnestly examined this phenomenon, and found out that metal precipitation is unevenly distributed in the vicinity of openings of the porous silicon substrate.

It is considered that the unevenly distributed metal precipitation in the vicinity of openings of the porous silicon substrate would be based on the following facts: that is, since porous silicon is highly susceptible to oxidation, it is easily oxidized when it is brought into contact with an electrolyte used in the electrodeposition treatment for causing precipitation of metal, and hence, when a metal is precipitated by carrying out the electrodeposition treatment on the porous silicon substrate, metal reduction reaction locally occurs simultaneously with the oxidation reaction of the porous silicon, and metal precipitation is unevenly distributed.

It is generally considered that when an electrodeposition treatment is carried out on a porous silicon substrate, the surface of the porous silicon substrate should be rendered hydrophilic for increasing the compatibility with the deposition liquid. However, on the contrary to this, the present inventors have carried out a hydrophobizing treatment on a porous silicon substrate before carrying out an electrodeposition treatment on the porous silicon substrate, and found out that even when a porous silicon substrate having a pore diameter of 5 nm or less is used in carrying out the electrodeposition treatment on the porous silicon substrate, it is possible to inhibit unevenly distributed metal precipitation in the vicinity of openings, and to precipitate metal evenly inside pores formed in the porous silicon substrate.

Although the present invention does not elucidate the reason why metal can be precipitated evenly inside pores formed in the porous silicon substrate as described above, the following basis is conceivable. When an electrodeposition treatment is carried out on a porous silicon substrate as is the conventional case, an oxidation film of silicon having hydrophilicity is formed on its surface owing to moisture contained in the deposition liquid, whereas, in the present invention, since the surface of the porous silicon substrate is rendered hydrophobic, water molecules are repelled on the surface of the porous silicon substrate, and the water molecules are prevented from being adsorbed on the surface of the porous silicon substrate, particularly on openings of the porous silicon substrate, and thus metal ions easily enter pores of the porous silicon substrate at the time of carrying out the electrodeposition treatment.

The hydrophobizing treatment is carried out at least on openings of pores of the porous silicon substrate. The above-mentioned opening means a pore wall exposed on the surface of the porous silicon. The expression of “carrying out a hydrophobizing treatment at least on openings of pores of the porous silicon substrate” means carrying out a hydrophobizing treatment on pore walls exposed on the surface of the porous silicon, thereby making the pore walls exhibit hydrophobicity when contact angle of water is measured. The contact angle of water of a pore wall to which a hydrophobizing treatment has been conducted can be measured, for example, by using a contact angle measuring device. The contact angle of water of a pore wall to which a hydrophobizing treatment has been conducted is preferably 90° or more, more preferably 100° or more, and furthermore preferably 110° or more from the viewpoint of the increase in hydrophobicity of openings of pores of the porous silicon substrate.

The method for carrying out a hydrophobizing treatment on a porous silicon substrate is not particularly limited as far as the hydrophobizing treatment is carried out at least on pore walls of the porous silicon substrate. The preferred method for carrying out a hydrophobizing treatment on a porous silicon substrate includes, for example, a method of carrying out a hydrophobizing treatment on a porous silicon substrate by using an organic compound having a carbon-carbon unsaturated double bond or a carbon-carbon unsaturated triple bond, and a hydrophobic group at its terminal, however, the present invention is not limited only to the method.

Examples of the organic compound having a carbon-carbon unsaturated double bond or a carbon-carbon unsaturated triple bond and a hydrophobic group at its terminal include an alkene compound having a hydrophobic group at its terminal, an alkyne compound having a hydrophobic group at its terminal, and the like. Since these organic compounds have a high reactivity with silicon, it is possible to carry out a hydrophobizing treatment on a porous silicon substrate, for example, by bringing the porous silicon substrate into contact with the organic compound in a solution of the organic compound, or bringing it into gas-phase contact with the organic compound in gas of the organic compound.

Examples of the alkene compound having a hydrophobic group at its terminal include alkene compounds having a carbon-carbon double bond at a terminal of carbon chain. Concrete examples of the alkene compound having a hydrophobic group at its terminal include a hydrocarbon compound having an unsaturated double bond at its terminal, such as ethylene or 1-dodecene, an aliphatic carboxylic acid alkyl ester having an unsaturated double bond at its terminal such as (meth)acrylic acid alkyl ester, and the like, however, the present invention is not limited only to those exemplified ones. The number of carbon atoms in the alkyl ester is preferably 1 to 8, more preferably 1 to 4, and further preferably 1 to 3, from the viewpoint of precipitating metal inside pores formed in the porous silicon substrate.

Concrete examples of the alkyne compound having a hydrophobic group at its terminal include alkyne compounds having a carbon-carbon triple bond at a terminal of carbon chain. Concrete examples of the alkyne compound having a hydrophobic group at its terminal include a hydrocarbon compound having an unsaturated triple bond at its terminal such as acetylene, an aliphatic carboxylic acid alkyl ester having an unsaturated triple bond at its terminal such as propiolic acid alkyl ester, and the like, however, the present invention is not limited only to those exemplified ones. The number of carbon atoms in the alkyl ester is preferably 1 to 8, more preferably 1 to 4, and further preferably 1 to 3 from the viewpoint of precipitating metal inside pores formed in the porous silicon substrate as is the case where the foregoing alkene compound having a hydrophobic group at its terminal is used.

Examples of a method for carrying out a hydrophobizing treatment on a porous silicon substrate by using the organic compound having a carbon-carbon unsaturated double bond or a carbon-carbon unsaturated triple bond, and a hydrophobic group at its terminal include a method of clipping the porous silicon substrate in a solution containing the organic compound having a carbon-carbon unsaturated double bond or a carbon-carbon unsaturated triple bond, and a hydrophobic group at its terminal, and the like, however, the present invention is not limited only to those exemplified ones. The liquid may be a liquid composed of the organic compound having a carbon-carbon unsaturated double bond or a carbon-carbon unsaturated triple bond, and a hydrophobic group at its terminal, or may be a solution prepared by dissolving the organic compound having a carbon-carbon unsaturated double bond or a carbon-carbon unsaturated triple bond, and a hydrophobic group at its terminal in an organic solvent. As the organic solvent, a nonaqueous organic solvent having a low polarity is preferred. Examples of the nonaqueous organic solvent having a low polarity include n-hexane, cyclohexane and the like, however, the present invention is not limited only to those exemplified ones. In carrying out a hydrophobizing treatment on a porous silicon substrate by bringing the porous silicon substrate into gas-phase contact with the organic compound in gas of the organic compound, hydrocarbon compounds having a carbon-carbon unsaturated bond that are gas in normal temperatures such as ethylene and acetylene may be used as the hydrocarbon compound.

Among the methods for carrying out a hydrophobizing treatment on a porous silicon substrate, a solution method in which a hydrophobizing treatment is carried out on a porous silicon substrate by using a solution prepared by dissolving the organic compound having a carbon-carbon unsaturated double bond or a carbon-carbon unsaturated triple bond, and a hydrophobic group at its terminal in an organic solvent is preferred because hydrophobization of the porous silicon substrate can be easily controlled. When the solution method is employed, the concentration of the organic compound having a carbon-carbon unsaturated double bond or a carbon-carbon unsaturated triple bond, and a hydrophobic group at its terminal in the solution is preferably 0.03 M or more, more preferably 0.05 M or more, and further preferably 0.1 M or more from the viewpoint of sufficiently carrying out the hydrophobizing treatment, and is preferably 10 M or less, more preferably 5 M or less, and further preferably 3 M or less from the viewpoint of easy control of the rate of the hydrophobizing treatment.

When a porous silicon substrate is clipped in a liquid containing the organic compound having a carbon-carbon unsaturated double bond or a carbon-carbon unsaturated triple bond, and a hydrophobic group at its terminal, the temperature of the liquid is preferably about 100° to about 200° C. when an organic compound having a carbon-carbon unsaturated double bond, and a hydrophobic group at its terminal is used, and is preferably about 20° to about 30° C. when an organic compound having a carbon-carbon unsaturated triple bond, and a hydrophobic group at its terminal is used.

The period of time required for carrying out the hydrophobizing treatment on a porous silicon substrate cannot be absolutely determined because it differs depending on the temperature at the time of carrying out the hydrophobizing treatment on the porous silicon substrate, however, it is typically, preferably 5 hours or more, more preferably 8 hours or more, and further preferably 10 hours or more from the viewpoint of sufficiently carrying out the hydrophobizing treatment, and preferably 25 hours or less, more preferably 20 hours or less, and further preferably 15 hours or less from the viewpoint of preventing the porous silicon substrate from being oxidized and making the hydrophobizing treatment sufficiently proceed when moisture is existed in the liquid at the time of carrying out the hydrophobizing treatment.

The hydrophobizing treatment can be carried out at least on the openings of pores of the porous silicon substrate. It is preferable to carry out the hydrophobizing treatment on the entire pore walls of the porous silicon substrate. When the method for carrying out a hydrophobizing treatment on a porous silicon substrate as described above is employed, it is possible to carry out the hydrophobizing treatment on the entire pore walls of the porous silicon substrate.

In the present invention, since the hydrophobizing treatment is carried out on the porous silicon substrate as described above, the phenomenon of unevenly distributed precipitation of metal in the openings of the porous silicon substrate can be prevented, and hence, the metal can be precipitated inside the pores of the porous silicon substrate by an electrodeposition treatment as described later.

Next, by carrying out the electrodeposition treatment on the porous silicon substrate to which a hydrophobizing treatment has been conducted in the manner as described above, a metal is precipitated inside the pores of the porous silicon substrate. Thus, a porous silicon material filled with a metal is obtained.

When an electrodeposition treatment is carried out on a porous silicon substrate, a deposition liquid is used. The deposition liquid may be prepared, for example, by dissolving in water a water-soluble salt of the metal that is to be precipitated inside pores of the porous silicon substrate.

Examples of the metal to be precipitated inside pores of the porous silicon substrate include gold, silver, copper, platinum, ruthenium, rhodium, palladium, osmium, iridium, lead, tin, alloys of such metal, and the like, however, the present invention is not limited only to those exemplified ones.

Examples of the water-soluble salt of metal include hexafluoroplatinate, ruthenium fluoride, palladium fluoride, iridium fluoride, rhodium fluoride, hexachloroplatinate, ruthenium chloride, palladium chloride, iridium chloride, rhodium chloride, hexabromoplatinate, ruthenium bromide, palladium bromide, iridium bromide, rhodium bromide, hexaiodoplatinate, ruthenium iodide, palladium iodide, iridium iodide, rhodium iodide, copper sulfate, zinc sulfate, silver nitrate, and the like, however, the present invention is not limited only to those exemplified ones. Examples of the salt include alkaline metal salts such as sodium salts and potassium salts, alkaline earth metal salts such as calcium salts and magnesium salts, and the like, however, the present invention is not limited only to those exemplified ones. Among the water-soluble salts of metal, hexachloroplatinate, hexabromoplatinate and hexaiodoplatinate are preferred, and hexabromoplatinate and hexaiodoplatinate are more preferred from the viewpoint of the increase in filling density of metal to be precipitated inside pores of the porous silicon substrate.

Typically, a metal ion concentration in a deposition liquid is preferably 0.03 to 3 M, more preferably 0.05 to 1 M, and further preferably 0.05 to 0.5 M from the viewpoint of precipitating metal rapidly and evenly inside pores of the porous silicon substrate.

The liquid temperature of a deposition liquid is preferably 0° to 25° C., more preferably 0° to 20° C., and further preferably 5° to 20° C. from the viewpoint of precipitating metal efficiently and sufficiently inside pores of the porous silicon substrate.

From the viewpoint of precipitating metal evenly inside pores of the porous silicon substrate, it is preferred to carry out the electrodeposition treatment while stirring the deposition liquid.

The electrodeposition treatment can be carried out by using a porous silicon substrate as an active electrode and an insoluble electrode of platinum, carbon or the like as a counter electrode, and applying a current between the porous silicon substrate as an anode and the insoluble electrode as a cathode via a deposition liquid.

A current density at the time of applying a current to the deposition liquid is preferably 0.5 μA/cm² or more, and more preferably 1 μA/cm² or more from the viewpoint of precipitating metal evenly inside pores of the porous silicon substrate, and is preferably 15 μA/cm² or less, and more preferably 10 μA/cm² or less from the viewpoint of precipitating metal sufficiently inside pores of the porous silicon substrate.

When a metal is precipitated continuously in the depth direction of pores of the porous silicon substrate in carrying out the electrodeposition treatment on the porous silicon substrate, it is possible to form fibrous metallic nanofibers in pores of the porous silicon substrate, whereas when a metal is precipitated discontinuously in the depth direction of pores of the porous silicon substrate, it is possible to form particulate metallic nanoparticles in pores of the porous silicon substrate.

Which one of fibrous metallic nanofibers and metallic nanop articles is to be formed in pores of the porous silicon substrate can be easily controlled by adjusting the current density at the time of applying a current to the deposition liquid.

When fibrous metallic nanofibers are to be formed inside pores of the porous silicon substrate by precipitating metal continuously in the depth direction, the upper limit of the current density at the time of applying a current to the deposition liquid is preferably 5 μA/cm² or less, more preferably 4.5 μA/cm² or less, and further preferably 4 μA/cm² or less. When particulate metallic nanop articles are to be formed inside pores of the porous silicon substrate by precipitating metal discontinuously in the depth direction, the lower limit of the current density at the time of applying a current to the deposition liquid is preferably 5 μA/cm² or more, more preferably 5.5 μA/cm² or more, and further preferably 6 μA/cm² or more.

When the current density at the time of applying a current to the deposition liquid is adjusted to about 5 μA/cm², and more specifically about 4.9 to about 5.1 μA/cm², it is possible to allow particulate metallic nanoparticles and fibrous metallic nanofibers to coexist.

In the manner as described above, it is possible to obtain a porous silicon material in which pores of a porous silicon substrate having pores of 1 to 5 nm in pore diameter and having a specific resistance of 5 to 20 Ω·cm are filled with a metal.

The porous silicon material of the present invention is excellent in mechanical strength because pores having a very small pore diameter of 1 to 5 nm are filled with a metal, and it is expected to be used, for example, for an electrode for a wet solar cell, an electrode for a fuel cell, and the like.

The metallic nanoparticles or nanofibers of the present invention can be produced by using the porous silicon material filled with a metal obtained above. More specifically, by dissolving silicon contained in the porous silicon material filled with a metal obtained above, it is possible to produce the metallic nanoparticles or nanofibers of the present invention. Which one of fibrous metallic nanofibers and particulate metallic nanoparticles is to be formed in pores of the porous silicon substrate can be controlled by adjusting the current density at the time of applying a current to the deposition liquid as described above.

Examples of a method for dissolving silicon contained in the porous silicon material filled with a metal include a method of carrying out a treatment on the porous silicon material filled with a metal by using a solution that dissolves silicon but does not dissolve a metal, and the like, however, the present invention is not limited only to those exemplified ones. Examples of a preferred method for dissolving silicon contained in the porous silicon material filled with a metal include a method of dipping the porous silicon material filled with a metal in a solution that dissolves silicon but does not dissolve a metal such as an aqueous tetramethyl ammonium hydroxide solution, and the like. In the method, the liquid temperature of the solution that dissolves silicon but does not dissolve a metal is preferably 85° to 95° C. from the viewpoint of rapid dissolution of silicon and improvement in safety. When an aqueous tetramethyl ammonium hydroxide solution is used as the solution that dissolves silicon but does not dissolve a metal, the concentration of tetramethyl ammonium hydroxide in the aqueous tetramethyl ammonium hydroxide solution is preferably about 15 to about 35% by weight, and more preferably about 20 to about 30% by weight from the viewpoint of rapid dissolution of silicon and improvement in safety.

The metallic nanop articles or nanofibers of the present invention obtained in the manner as described above are expected for use as an electrode material for a fuel cell or the like, a catalyst material, a biosensing material in dynamic analysis of protein, and the like because they have a high specific surface area.

### EXAMPLES

Next, the present invention will be described more specifically based on working examples, however, the present invention is not limited only to those examples.

### Example 1

A silicon substrate [length 1 cm×width 1 cm×thickness 600 μm, commercially available from SUMCO CORPORATION, p-type silicon (100), specific resistance 0.01 Ω·cm] was prepared. An ethanol solution containing 22% by weight of hydrogen fluoride was prepared, and a porous silicon substrate was produced by using the silicon substrate as an active electrode and a platinum bar as a counter electrode, and applying a current at a current density of 2 mA/cm² for 20 minutes under the condition of room temperature.

The porous silicon substrate obtained in the above was observed by a scanning electron microscope [commercially available from JEOL Ltd., product number: JSM 6500FE] and a transmission electron microscope [commercially available from JEOL Ltd., Product number: JEM-2200FS], and the average diameter in the planner direction of the porous silicon substrate and the depth along the thickness of the porous silicon substrate were observed for 100 pores, and the average diameter of pores in the planner direction was 3 nm, and the depth along the thickness was 2 μm. Since the maximum value and the minimum value of the pore diameters of pores formed in the porous silicon substrate fell within the range of ±2 nm of the average diameter, it was confirmed that pores formed in the porous silicon substrate were very even.

Next, for carrying out a hydrophobizing treatment on the porous silicon substrate, a 0.1 M methyl propiolate solution in n-hexane was prepared by dissolving methyl propiolate in n-hexane by using methyl propiolate as an organic compound having a carbon-carbon unsaturated triple bond and a hydrophobic group at its terminal.

By clipping the porous silicon substrate obtained above in the 0.1 M methyl propiolate solution in n-hexane in an argon gas atmosphere at room temperature for 15 hours, a hydrophobizing treatment was carried out on the porous silicon substrate. Whether or not the hydrophobizing treatment was carried out on the porous silicon substrate was confirmed by a Fourier transform infrared spectrophotometer (FT-IR). As a result, successful conduction of the hydrophobizing treatment on pore walls of the porous silicon substrate was confirmed.

Using the porous silicon substrate to which a hydrophobizing treatment has been conducted obtained in the above as an electrode, and using an aqueous solution containing 0.1 M potassium hexachloroplatinate and 0.5 M sodium chloride as an electrolyte, a current was applied at a constant current density of 6.4 μA/cm² for 30 minutes, to obtain a porous silicon material. The obtained porous silicon material was observed by a scanning electron microscope and a transmission electron microscope, and it was confirmed that platinum was evenly formed inside pores.

Next, by clipping the porous silicon material obtained in the above in an aqueous solution containing 25% by weight of tetramethyl ammonium hydroxide at a liquid temperature of 90° C., silicon contained in the porous silicon material was dissolved, and particulate metallic nanoparticles were collected.

### Example 2

A porous silicon material and particulate metallic nanoparticles were obtained by carrying out the same procedures as in Example 1, except that a 0.1 M 1-dodecene solution in n-hexane was used in place of the 0.1 M methyl propiolate solution in n-hexane in Example 1. The obtained porous silicon material was observed in the same manner as in Example 1, and it was confirmed that platinum was evenly formed inside pores.

### Comparative Example 1

A porous silicon material was produced in the same manner as in Example 1 except that the hydrophobizing treatment was not carried out on the porous silicon substrate in Example 1, and it was confirmed that platinum precipitated in the form of particles in openings of pores formed in the porous silicon material, and particulate metallic nanoparticles were not formed inside the pores.

### Comparative Example 2

A hydrophilizing treatment was carried out in the same manner as in Example 1, except that the porous silicon substrate was clipped in a 0.1 M propiolic acid (an organic compound having a carbon-carbon unsaturated double bond and having a carboxylic group which is a hydrophilic group at its terminal) solution in n-hexane in an argon gas atmosphere in place of the hydrophobizing treatment on the porous silicon substrate in Example 1. Successful conduction of the hydrophilizing treatment on the porous silicon substrate was confirmed by a Fourier transform infrared spectrophotometer (FT-IR).

Next, a porous silicon material was produced in the same manner as in Example 1 by using the porous silicon substrate, to which a hydrophobizing treatment has been conducted, obtained in the above, and it was confirmed that platinum little precipitated inside pores of the porous silicon material and platinum precipitated in an upper part of the porous layer as a continuous film. This demonstrates the impossibility of producing metallic nanoparticles and metallic nanofibers having a pore diameter of less than 10 nm by Comparative Example 2.

### Example 3 and Comparative Example 3

After ultrasonically washing a silicon substrate [length 1 cm×width 1 cm×thickness 600 μm, commercially available from SUMCO CORPORATION, p-type silicon (100), specific resistance 0.01 Ω·cm] with acetone and ultrapure water respectively for 5 minutes, the silicon substrate was clipped in an aqueous solution containing 5% by weight of hydrogen fluoride for 10 minutes. Thereafter, the silicon substrate was anode-oxidized with an aqueous solution containing 22% by weight of hydrogen fluoride, to prepare a porous silicon substrate.

After washing the porous silicon substrate obtained in the above five times with ultrapure water, the porous silicon substrate underwent a hydrophobizing treatment or a hydrophilizing treatment.

When the porous silicon substrate underwent the hydrophobizing treatment (Example 3), the porous silicon substrate was clipped in a 0.1 M methyl propiolate solution in anhydrous hexane (a solution prepared by dissolving 0.13 mL of methyl propiolate in 14.9 mL of anhydrous hexane) in an argon gas atmosphere for 15 hours, and then the porous silicon substrate to which a hydrophobizing treatment has been conducted was taken out from the solution of methyl propiolate in anhydrous hexane.

On the other hand, when the porous silicon substrate underwent the hydrophilizing treatment (Comparative Example 3), the porous silicon substrate was clipped in a 0.1 M propiolic acid solution in anhydrous hexane (a solution prepared by dissolving 0.1 mL of propiolic acid in 14.9 mL of anhydrous hexane) in an argon gas atmosphere for 15 hours, and then the porous silicon substrate to which a hydrophobizing treatment has been conducted was taken out from the solution of propiolic acid in anhydrous hexane.

The porous silicon substrate to which a hydrophobizing treatment has been conducted and the porous silicon substrate to which a hydrophobizing treatment has been conducted obtained in the above were respectively washed twice with hexane and ten times with ethanol and water.

Thereafter, by using the porous silicon substrate to which a hydrophobizing treatment has been conducted and the porous silicon substrate to which a hydrophobizing treatment has been conducted obtained in the above respectively as electrodes, and using an aqueous solution containing 0.1 M potassium hexachloroplatinate and 0.5 M sodium chloride as an electrolyte, a current was applied at a constant current density of 6.4 μA/cm² for 30 minutes, to obtain a porous silicon material.

The cross section of each of the porous silicon materials obtained in the above was observed by a scanning electron microscope (commercially available from JEOL Ltd., product number: JSM 6500FE).

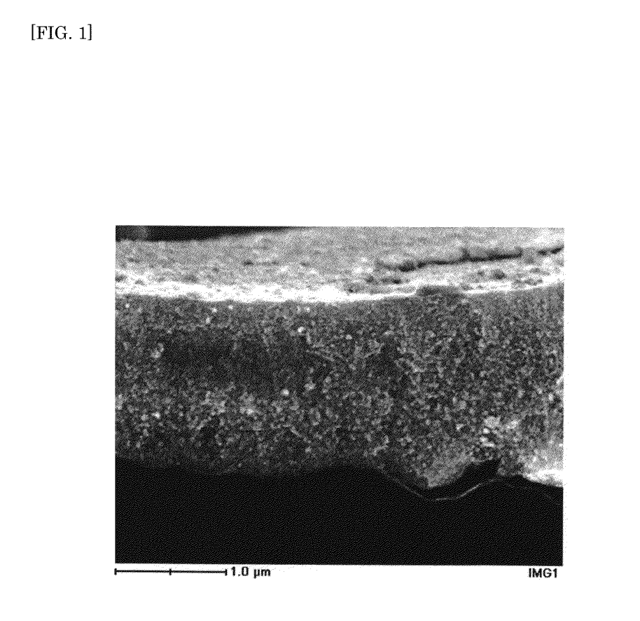

FIG. 1 is a photograph of an image taken under a scanning electron microscope of a cross section of the porous silicon substrate, in which the porous silicon substrate to which a hydrophobizing treatment has been conducted obtained in Example 3 is used. As can be seen in FIG. 1, there is a porous layer in the region between the dense white part in the upper part and the black part in the lower part of the photograph.

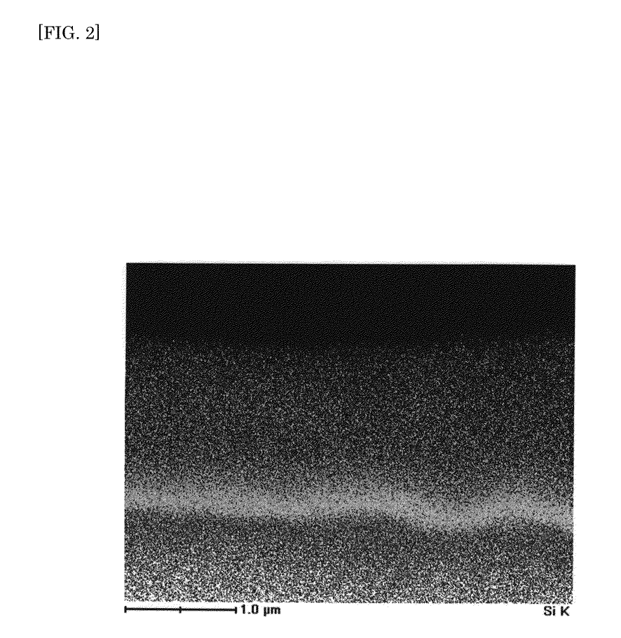

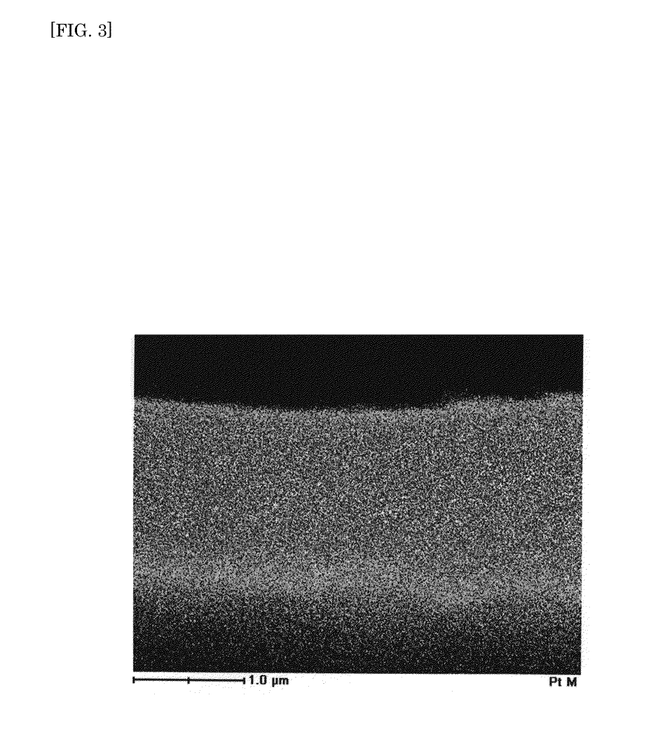

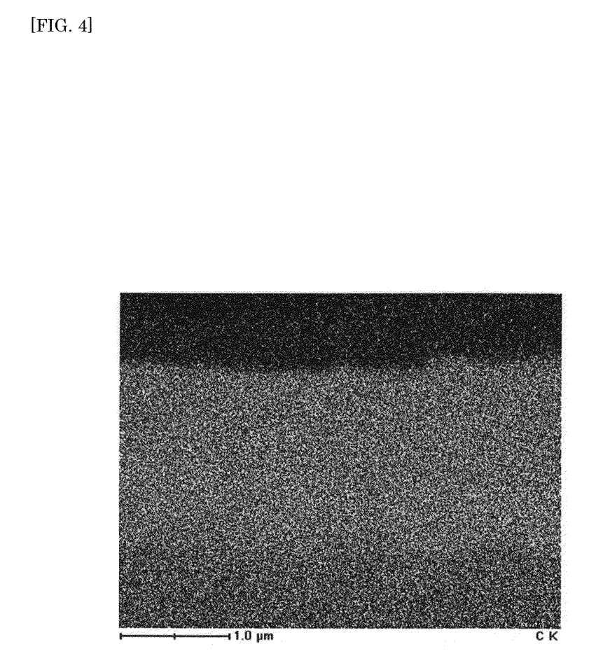

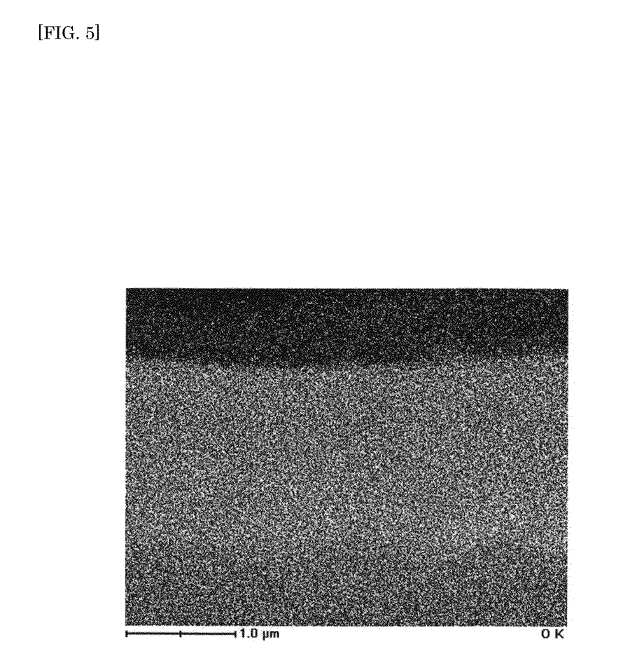

The cross section of the porous silicon substrate obtained in Example 3 was analyzed by energy dispersive X-ray analysis, and distributions of silicon atoms, platinum atoms, carbon atoms and oxygen atoms were examined, respectively. Photographs taken under energy dispersive X-ray showing distributions of silicon atoms, platinum atoms, carbon atoms and oxygen atoms are shown in this order in FIGS. 2 to 5, respectively. The result shown in FIG. 2 demonstrates the presence of a small amount of silicon atoms in the region from the black part located in the upper part of the photograph to the whitish band-like part in the lower part of the photograph. Also, FIG. 2 demonstrates the presence of platinum atoms in the broad pale color region spanning from the lower end of the black part in the upper part to the upper end of the black part in the lower part of FIG. 3. The results shown in FIG. 4 and FIG. 5 demonstrate the presence of both carbon atoms and oxygen atoms in the porous layer.

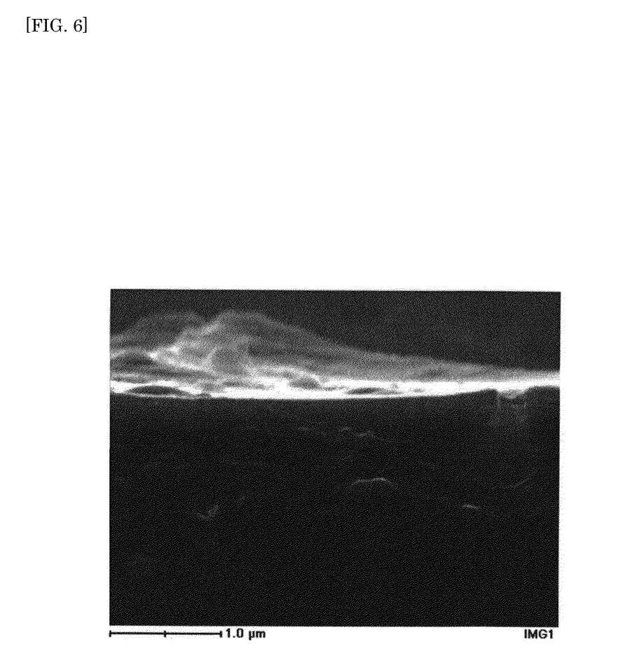

FIG. 6 is a photograph of an image taken under a scanning electron microscope of a cross section of the porous silicon substrate, in which the porous silicon substrate to which a hydrophobizing treatment has been conducted obtained in Comparative Example 3 is used. As can be seen in FIG. 6, there is a white part showing a porous layer in the region spanning from the white part in the upper part of the photograph to the white part in the lower part of the photograph.

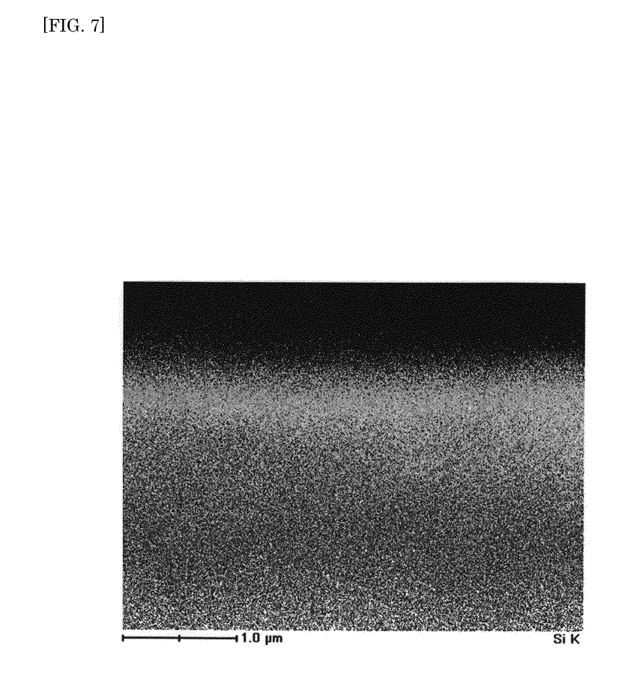

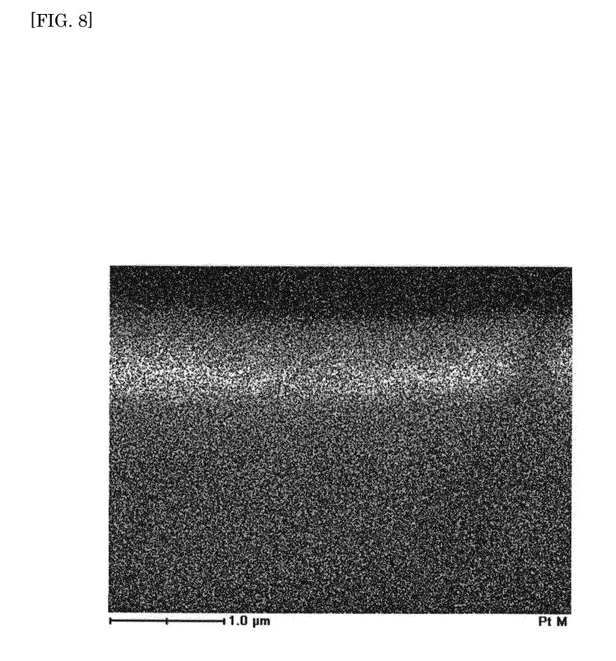

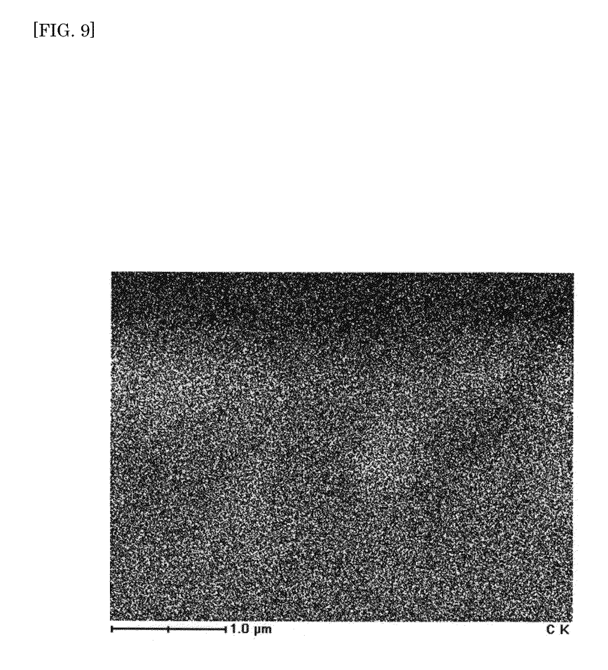

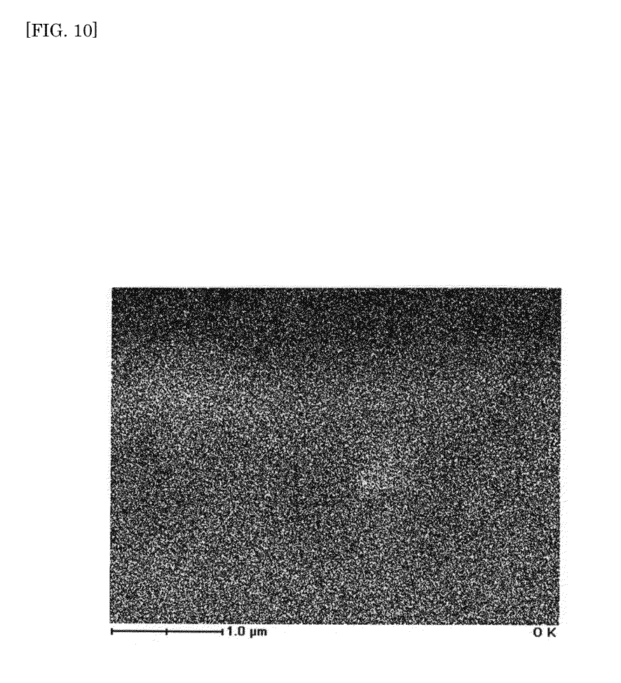

The cross section of the porous silicon substrate obtained in Comparative Example 3 was analyzed by energy dispersive X-ray analysis, and distributions of silicon atoms, platinum atoms, carbon atoms and oxygen atoms were examined, respectively. Photographs taken under energy dispersive X-ray showing distributions of silicon atoms, platinum atoms, carbon atoms and oxygen atoms are shown in this order in FIGS. 7 to 10, respectively. The result shown in FIG. 7 demonstrates the presence of silicon atoms in the region other than the black part located in the upper part of the photograph. Also, it demonstrates that there are platinum atoms in the narrow pale color part in the upper part of FIG. 8. The results shown FIG. 9 and FIG. 10 demonstrate the presence of both carbon atoms and oxygen atoms in the porous layer.

These results show that when the hydrophilizing treatment is carried out on the porous silicon substrate as shown in Comparative Example 3, platinum precipitates on the porous layer surface and in openings of pores of the porous silicon substrate. To the contrary, when the hydrophobizing treatment is carried out on the porous silicon substrate as shown in Example 3, platinum precipitates from inside to bottoms of pores of the porous silicon substrate in comparison with the case where the hydrophilizing treatment is carried out thereon.

### Example 4

A porous silicon substrate was prepared in the same manner as in Example 1 except that in place of the aqueous solution containing 0.1 M potassium hexachloroplatinate and 0.5 M sodium chloride, an aqueous solution containing 0.2 M potassium chloride and 0.5 M sodium chloride was used as a solution in which platinum ions were removed from the foregoing solution in Example 1, and the porous silicon substrate was clipped in the aqueous solution for 2 hours. As a result, dissolution of the porous layer in the obtained porous silicon material was confirmed.

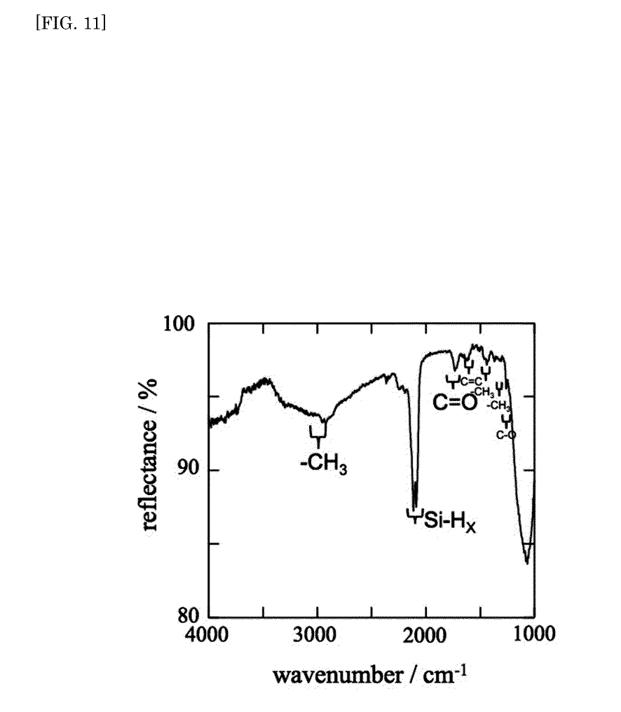

After carrying out an electrodeposition treatment on the porous silicon material in which the porous layer is dissolved in the same manner as in Example 1, the porous layer where platinum precipitated was scraped off, and the Fourier transform infrared spectroscopy of the scraped porous layer was examined. The result is shown in FIG. 11.

In FIG. 11, “wave number/cm⁻¹” means “wave number (cm⁻¹)”, and “reflectance/%” means “reflectance (%)”. The same can be applied to the subsequent drawings.

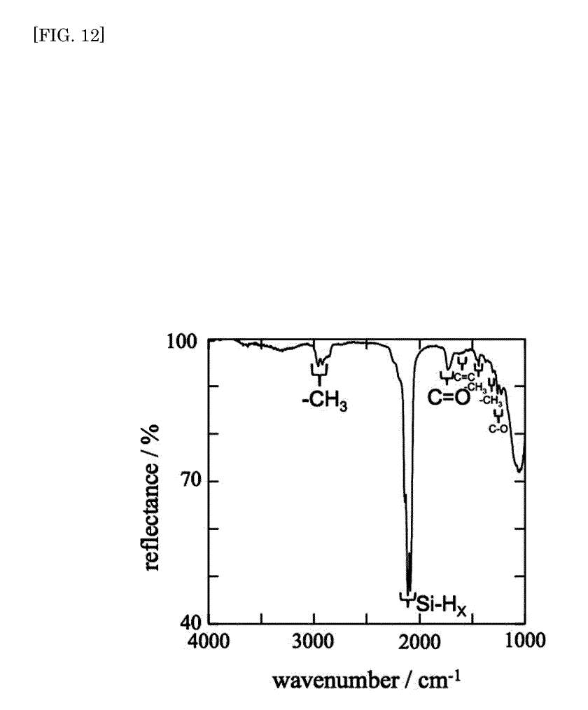

For reference, the Fourier transform infrared spectroscopy of the porous layer that was scraped off before carrying out an electrodeposition treatment on the porous silicon material in which the porous layer was dissolved was examined. The result is shown in FIG. 12.

### Comparative Example 4

A porous silicon substrate was prepared in the same manner as in Comparative Example 2, except that in place of the aqueous solution containing 0.1 M potassium hexachloroplatinate and 0.5 M sodium chloride, an aqueous solution containing 0.2 M potassium chloride and 0.5 M sodium chloride was used as a solution in which platinum ions were removed from the foregoing solution in Comparative Example 2, and the porous silicon substrate was dipped in the aqueous solution for 2 hours. As a result, dissolution of the porous layer in the obtained porous silicon material was confirmed.

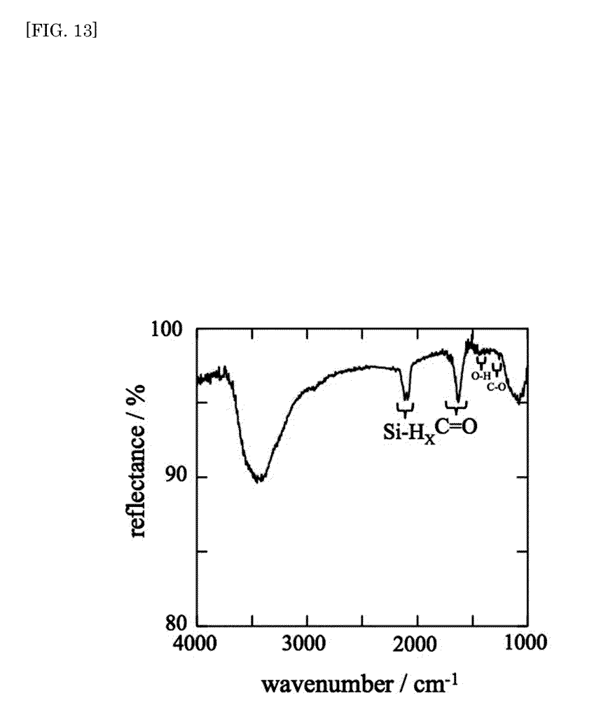

After carrying out an electrodeposition treatment on the porous silicon material in which the porous layer is dissolved in the same manner as in Comparative Example 2, the porous layer where platinum precipitated was scraped off, and the Fourier transform infrared spectroscopy of the scraped porous layer was examined. The result is shown in FIG. 13.

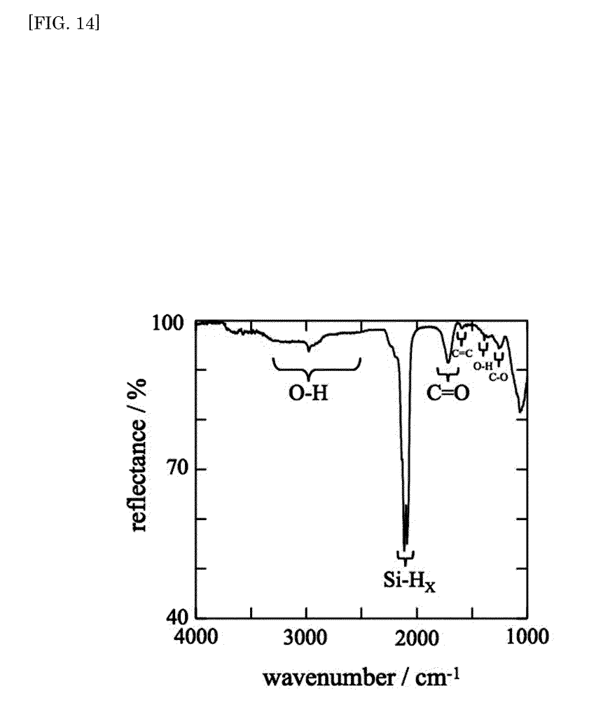

For reference, the Fourier transform infrared spectroscopy of the porous layer that was scraped off before carrying out an electrodeposition treatment on the porous silicon material in which the porous layer was dissolved was examined. The result is shown in FIG. 14.

From the experimental result of Comparative Example 4, it is considered that a —COOH group is present in part of pore walls of the porous layer because a peak of Si—H stretching appears near a wave number of 2200 cm⁻¹, and a peak of C═O stretching appears near 1700 cm⁻¹, and a peak of O—H stretching broadly appears near 2500 to 3300 cm⁻¹ as shown in FIG. 13.

On the other hand, from the experimental result of Example 4, it is considered that a —COOCH₃ group is present in part of pore walls of the porous layer because a peak of C═O stretching appears near a wave number of 1700 cm⁻¹, and a peak of O—H stretching does not appear as shown in FIG. 11.

### Example 5

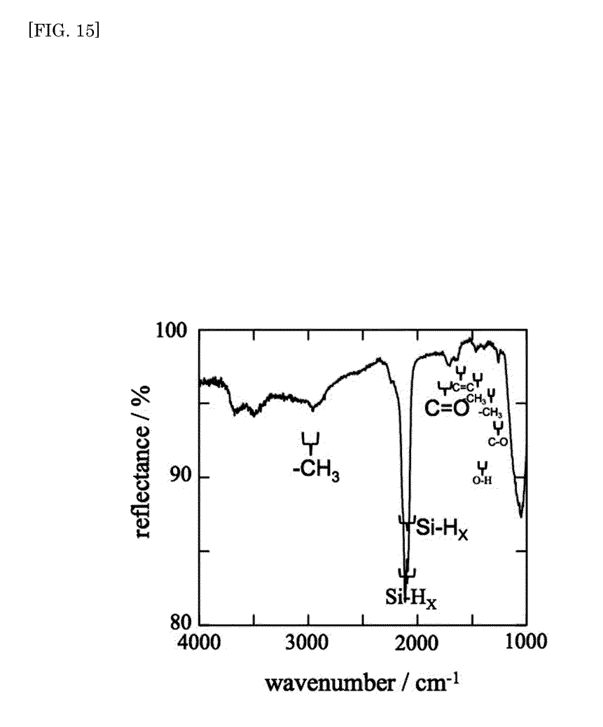

After preparing a porous silicon substrate to which a hydrophobizing treatment has been conducted in the same manner as in Example 1, the porous silicon substrate underwent a hydrolysis treatment by being dipped in a 2.0 M hydrochloric aqueous solution at 70° C. for 2 hours, and then whether or not the porous silicon substrate was hydrolyzed was examined by infrared absorption spectroscopy. The result is shown in FIG. 15.

FIG. 15 is a view showing the measurement result of infrared absorption of the porous silicon substrate. As shown in FIG. 15, it is considered that the porous silicon substrate is not hydrolyzed by an acid because a clear peak of O—H stretching was not detected.

### Example 6

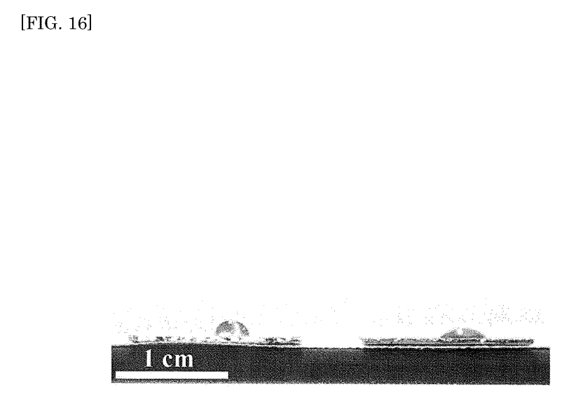

For the porous silicon substrate to which a hydrophobizing treatment has been conducted obtained in Example 1, and the porous silicon substrate, to which the hydrophilizing treatment was conducted, obtained in Comparative Example 2, an image of the shape of a water drop at the time of contact with the porous silicon to which a hydrophobizing treatment has been conducted or the porous silicon, to which the hydrophilizing treatment was conducted, taken with a digital camera (commercially available from Nikon Corporation, product number: D90). The result is shown in FIG. 16. In FIG. 16, the left water drop is present on the porous silicon substrate to which a hydrophobizing treatment has been conducted obtained in Example 1, and the right water drop is present on the porous silicon substrate, to which the hydrophilizing treatment was conducted, obtained in Comparative Example 2.

The result shown in FIG. 16 demonstrates that the porous silicon substrate to which a hydrophobizing treatment has been conducted obtained in Example 1 is markedly superior in hydrophobicity to the porous silicon substrate to which the hydrophilizing treatment was conducted obtained in Comparative Example 2.

### Example 7

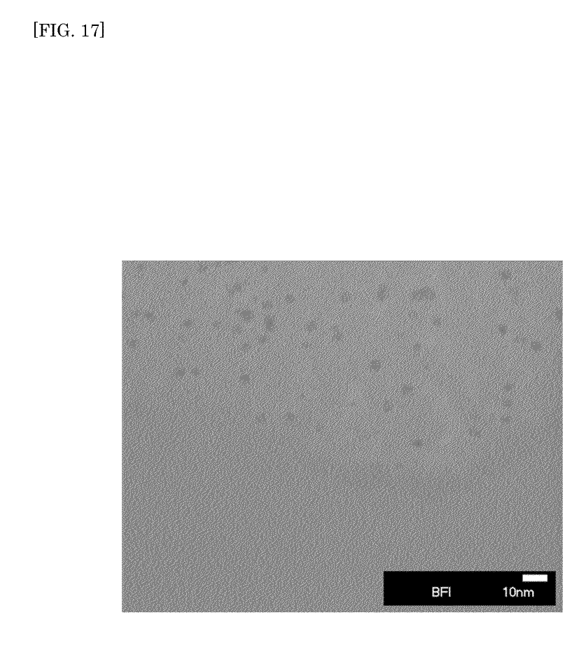

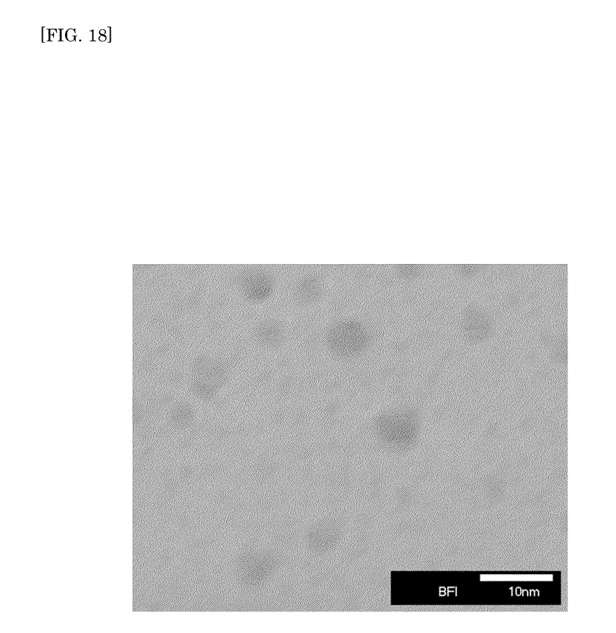

The porous silicon substrate to which a hydrophobizing treatment has been conducted obtained in Example 1 was processed with a focused ion beam processing device (commercially available from JEOL Ltd., product number: JIB-4500), and a sample having a thickness of 0.1 μm was prepared. The obtained sample was observed by a field emission transmission electron microscope (commercially available from JEOL Ltd., product number: JEM-2200FS). The result is shown in FIG. 17 and FIG. 18. FIG. 17 and FIG. 18 show transmission electron photographs of the aforementioned sample, respectively, and FIG. 18 is a transmission electron photograph taken at a larger magnifying power than the transmission electron photograph of FIG. 17.

FIG. 17 and FIG. 18 demonstrate that the spotted black dots are platinum particles, and particle diameters of the platinum particles are about 5 nm at maximum, and about 3 to about 4 nm on average.

### Example 8

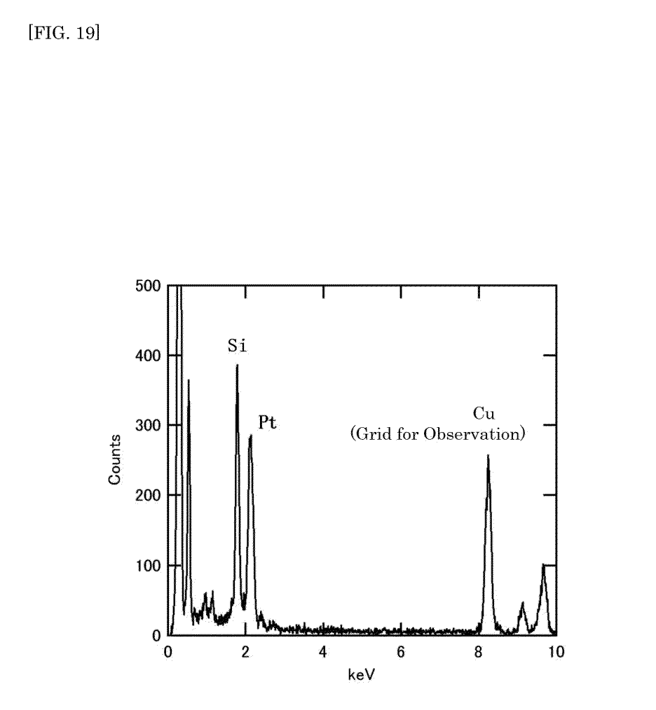

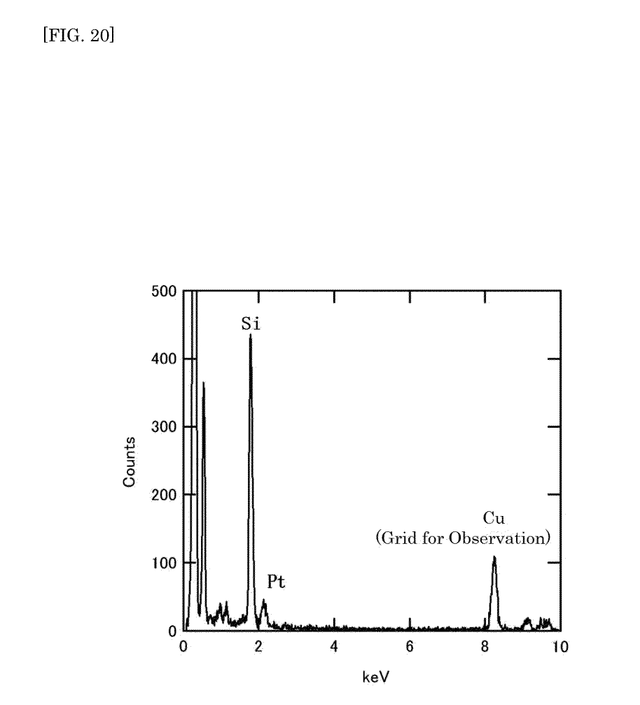

By an energy dispersive X-ray analyzer attached to the field emission transmission electron microscope (commercially available from JEOL Ltd, product number: JEM-2200FS) used in Example 7, the composition of the porous silicon substrate to which a hydrophobizing treatment has been conducted obtained in Example 1 was analyzed. The result is shown in FIG. 19 and FIG. 20. FIG. 19 shows a measurement result of the energy dispersive X-ray analysis in the site where platinum particles are present in the porous silicon substrate, and FIG. 20 shows a measurement result of the energy dispersive X-ray analysis in the site where platinum particles are absent in the porous silicon substrate.

From the comparison of FIG. 19 with FIG. 20, it was confirmed that the platinum particles that were present in the porous silicon substrate were composed of platinum.

### Example 9

By dipping the porous silicon substrate to which a hydrophobizing treatment has been conducted obtained in Example 1 in an aqueous solution containing 25% of tetramethyl ammonium hydroxide heated to 90° C. for 1 second, only the porous layer was completely dissolved. The weight at this time was measured by using a high-precision electric balance (commercially available from Mettler-Toledo International Inc., product name: Ultramicro balance XP2UV).

Next, the porosity of the porous silicon substrate was calculated in accordance with the literature (V. Lehmann, Electrochemistry of Silicon: Instrumentation, Science, Materials and Applications, Wiley-VCH, 2002), by the equation:

P=[(m₁−m₂)/(m₁−m₃)]×100

wherein P represents porosity (%), m₁, m₂ and m₃ represent in this order weight before anode oxidation, weight after anode oxidation and weight after chemical dissolution of the porous layer, respectively. As a result, the porosity of the porous silicon substrate was 73%.

### Example 10

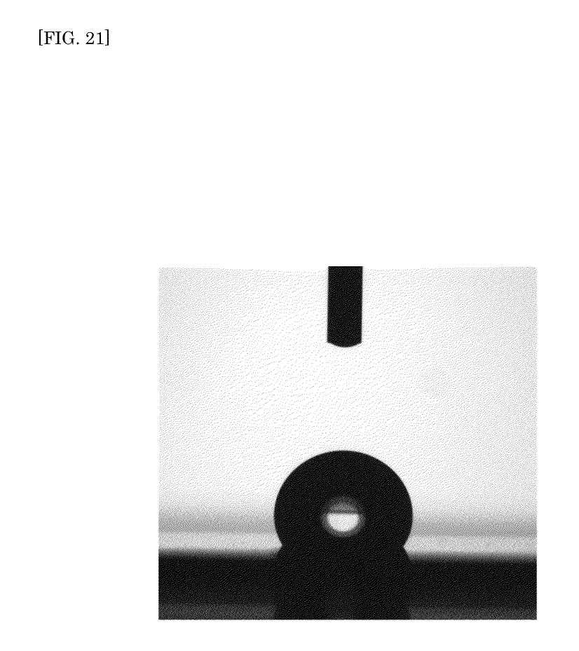

Ultrapure water in an amount of 10 μL purified by an ultrapure water producing apparatus (commercially available from Millipore Corporation, product name: Milli-Q Gradient-A10) was dropped on the surface of the porous silicon substrate, to which a hydrophobizing treatment has been conducted, obtained in Example 1, and a contact angle was measured by a contact angle measuring device (commercially available from KSV Instruments Ltd., product number: CAM200). As a result, the contact angle of the porous silicon substrate against water was 122 degrees. An optical photograph of water drops on the porous silicon substrate at this time is shown in FIG. 21.

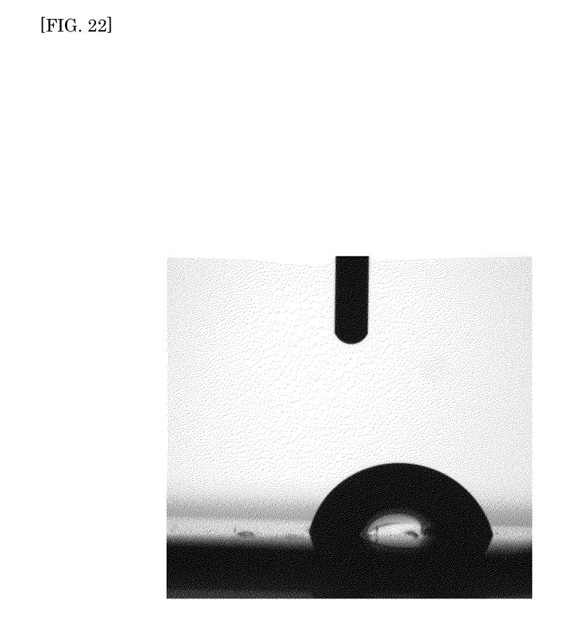

On the other hand, ultrapure water was dropped on the surface of the porous silicon substrate, to which the hydrophilizing treatment was conducted, obtained in Comparative Example 2, and a contact angle was measured in the same manner as described in the above. As a result, the contact angle of water to the porous silicon substrate was 78 degrees. An optical photograph of water drops on the porous silicon substrate at this time is shown in FIG. 22.

From the above results, it was confirmed that the porous silicon substrate to which a hydrophobizing treatment has been conducted obtained in Example 1 had a hydrophobic surface, and that the porous silicon substrate to which the hydrophilizing treatment was conducted obtained in Comparative Example 2 had a hydrophilic surface.

### Example 11

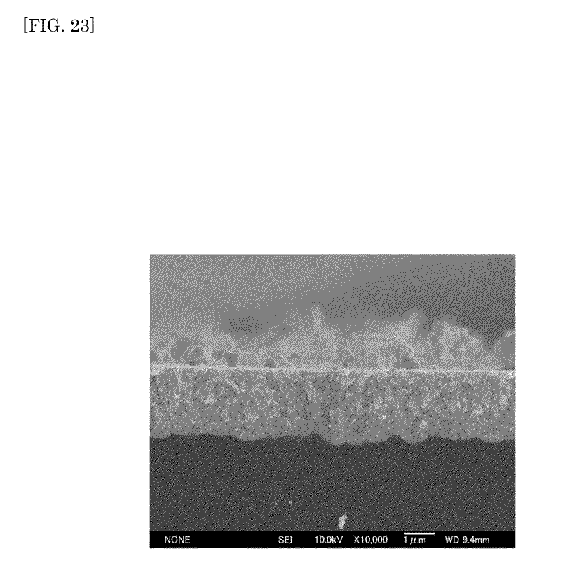

After the deposition of the porous silicon substrate to which a hydrophobizing treatment has been conducted obtained in Example 1 with platinum, a cross section of the porous silicon material was observed by a scanning electron microscope [commercially available from JEOL Ltd., product number: JSM 6500FE]. The result is shown in FIG. 23.

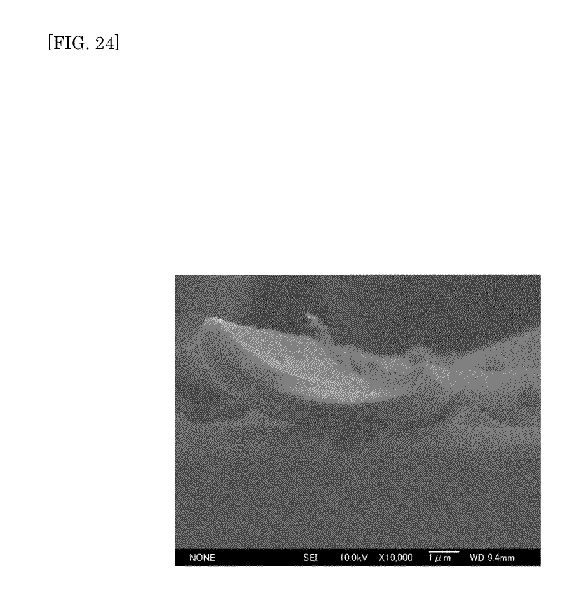

On the other hand, after the deposition of the porous silicon substrate to which the hydrophilizing treatment was conducted obtained in Comparative Example 2 with platinum in the same manner as described in the above, a cross section of the porous silicon material was observed by a scanning electron microscope [commercially available from JEOL Ltd., product number: JSM 6500FE]. The result is shown in FIG. 24.

From the results shown in FIG. 23 and FIG. 24, it can be seen that when the porous silicon substrate to which a hydrophobizing treatment has been conducted obtained in Example 1 is plated with platinum, the platinum deposition film is evenly formed on the surface, whereas when the porous silicon substrate to which the hydrophilizing treatment was conducted obtained in Comparative Example 2 is plated with platinum, peeling occurs in the porous silicon substrate. This facts demonstrate that the porous silicon substrate to which a hydrophobizing treatment has been conducted obtained in Example 1 is excellent in mechanical strength for the deposition film.

### Example 12

A silicon substrate [length 1 cm×width 1 cm×thickness 600 μm, commercially available from SUMCO CORPORATION, p-type silicon (100), specific resistance 0.01 Ω·cm] was prepared. An ethanol solution containing 22% by weight of hydrogen fluoride was prepared, and a porous silicon substrate was produced by using the silicon substrate as an active electrode and a platinum bar as a counter electrode, and applying a current at a current density of 2 mA/cm² for 20 minutes under the condition of room temperature.

The porous silicon substrate obtained in the above was observed by a scanning electron microscope (commercially available from JEOL Ltd., product number: JSM 6500FE) and a transmission electron microscope (commercially available from JEOL Ltd., Product number: JEM-2200FS), and an average diameter in the planner direction of the porous silicon substrate and a depth along the thickness of the porous silicon substrate were observed for 100 pores. As a result, the average diameter of pores in the planner direction was 3 nm, and the depth along the thickness was 2 μm. Since the maximum value and the minimum value of pore diameters of pores formed in the porous silicon substrate fell within the range of ±2 nm of the average diameter, it was confirmed that pores formed in the porous silicon substrate were very even.

Next, in order to carry out a hydrophobizing treatment on the porous silicon substrate, a 0.1 M methyl propiolate solution in n-hexane was prepared by dissolving methyl propiolate in n-hexane by using methyl propiolate as an organic compound having a carbon-carbon unsaturated triple bond and a hydrophobic group at its terminal.

By dipping the porous silicon substrate obtained in the above in the 0.1 M methyl propiolate solution in n-hexane in an argon gas atmosphere at room temperature for 15 hours, a hydrophobizing treatment was carried out on the porous silicon substrate. Whether or not the hydrophobizing treatment was carried out on the porous silicon substrate was confirmed by a Fourier transform infrared spectrophotometer (FT-IR). As a result, successful conduction of the hydrophobizing treatment on pore walls of the porous silicon substrate was confirmed.

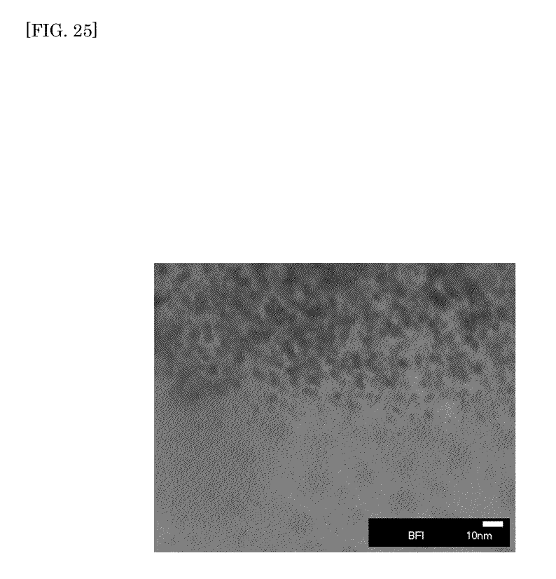

By using the porous silicon substrate to which a hydrophobizing treatment has been conducted obtained in the above as an electrode, using an aqueous solution containing 0.1 M potassium hexabromoplatinate and 0.1 M sulfuric acid as an electrolyte, and applying a current at a constant current density of 6.4 μA/cm² for 30 minutes, a porous silicon material was obtained. The energy dispersive X-ray analysis was carried out for the obtained porous silicon material, and distributions of platinum atoms and oxygen atoms were examined. The result is shown in FIG. 25.

Next, by clipping the porous silicon material obtained in the above in an aqueous solution containing 25% by weight of tetramethyl ammonium hydroxide at a liquid temperature of 90° C., silicon contained in the porous silicon material was dissolved, and particulate metallic nanoparticles were collected.

### Example 13

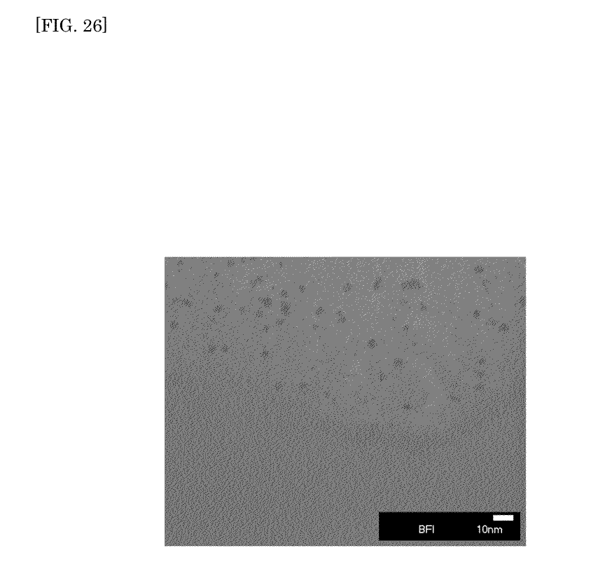

A porous silicon material was obtained by carrying out the same procedures as in Example 12, except that 0.1 M potassium hexachloroplatinate was used in place of 0.1 M potassium hexabromoplatinate in Example 12. The energy dispersive X-ray analysis was carried out for the obtained porous silicon material, and distributions of platinum atoms and oxygen atoms were examined. The result is shown in FIG. 26.

Next, by dipping the porous silicon material obtained in the above in an aqueous solution containing 25% by weight of tetramethyl ammonium hydroxide at a liquid temperature of 90° C., silicon contained in the porous silicon material was dissolved and particulate metallic nanoparticles were collected.

From the results shown in FIG. 25 and FIG. 26, it can be seen that the black part located in the upper part of the photograph shows the presence of platinum, and that the abundance of platinum is greater in the porous silicon material obtained in Example 12 than in the porous silicon material obtained in Example 13. It can be seen from this fact that the porous silicon material can be filled with a metal more densely when a bromine atom rather than a chlorine atom is used in a metal complex ion containing a halogen atom.

### Example 14

A silicon substrate [length 1 cm×width 1 cm×thickness 600 μm, commercially available from SUMCO CORPORATION, p-type silicon (100), specific resistance 0.01 Ω·cm] was prepared. An ethanol solution containing 22% by weight of hydrogen fluoride was prepared, and a porous silicon substrate was produced by using the silicon substrate as an active electrode and a platinum bar as a counter electrode, and applying a current at a current density of 2 mA/cm² for 20 minutes under the condition of room temperature.

The porous silicon substrate obtained in the above was observed by a scanning electron microscope (commercially available from JEOL Ltd., product number: JSM 6500FE) and a transmission electron microscope (commercially available from JEOL Ltd., Product number: JEM-2200FS), and an average diameter in the planner direction of the porous silicon substrate and a depth along the thickness of the porous silicon substrate were observed for 100 pores. As a result, the average diameter of pores in the planner direction was 3 nm, and the depth along the thickness was 2 μm. Since the maximum value and the minimum value of pore diameters of pores formed in the porous silicon substrate fell within the range of ±2 nm of the average diameter, it was confirmed that pores formed in the porous silicon substrate were very even.

Next, in order to carry out a hydrophobizing treatment on the porous silicon substrate, a 0.1 M methyl propiolate solution in n-hexane was prepared by dissolving methyl propiolate in n-hexane, and using methyl propiolate as an organic compound having a carbon-carbon unsaturated triple bond and a hydrophobic group at its terminal.

By dipping the porous silicon substrate obtained above in the 0.1 M methyl propiolate solution in n-hexane in an argon gas atmosphere at room temperature for 15 hours, a hydrophobizing treatment was carried out on the porous silicon substrate. Whether or not the hydrophobizing treatment was carried out on the porous silicon substrate was confirmed by a Fourier transform infrared spectrophotometer (FT-IR). As a result, successful conduction of the hydrophobizing treatment on pore walls of the porous silicon substrate was confirmed.

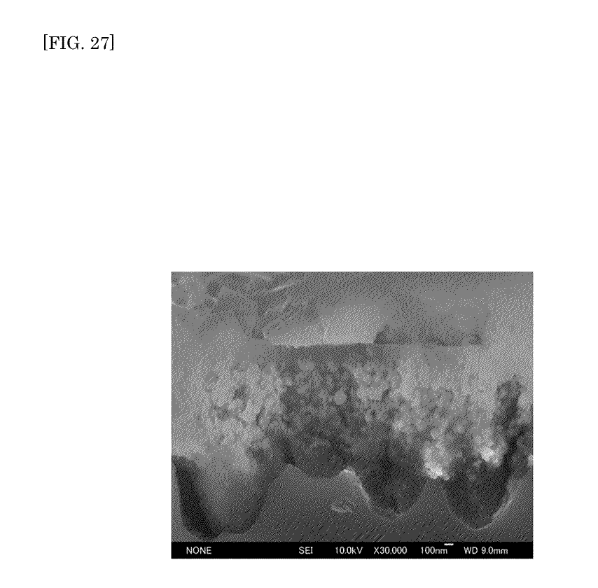

The porous silicon substrate to which a hydrophobizing treatment has been conducted obtained above as an electrode, and an aqueous solution containing 0.1 M copper sulfate and 0.1 M sulfuric acid as an electrolyte were used, and a current was applied at a constant current density of 6.4 μA/cm² for 30 minutes, to obtain a porous silicon material. The obtained porous silicon material was observed by a scanning electron microscope. The result is shown in FIG. 27.

Next, by clipping the porous silicon material obtained in the above in an aqueous solution containing 25% by weight of tetramethyl ammonium hydroxide at a liquid temperature of 90° C., silicon contained in the porous silicon material was dissolved and particulate metallic nanoparticles were collected.

### Comparative Example 5

A silicon substrate [length 1 cm×width 1 cm×thickness 600 μm, commercially available from SUMCO CORPORATION, p-type silicon (100), specific resistance 0.01 Ω·cm] was prepared. An ethanol solution containing 22% by weight of hydrogen fluoride was prepared. The silicon substrate as an active electrode and a platinum bar as a counter electrode were used, and a current was applied for 20 minutes at a current density of 2 mA/cm² at room temperature to prepare a porous silicon substrate.

The porous silicon substrate obtained in the above was observed by a scanning electron microscope (commercially available from JEOL Ltd., product number: JSM 6500FE) and a transmission electron microscope (commercially available from JEOL Ltd., Product number: JEM-2200FS), and an average diameter in the planner direction of the porous silicon substrate and a depth along the thickness of the porous silicon substrate were observed for 100 pores. As a result, it was confirmed that the average diameter of pores in the planner direction was 3 nm, and the depth along the thickness was 2 μm. Since the maximum value and the minimum value of pore diameters of pores formed in the porous silicon substrate fell within the range of ±2 nm of the average diameter, it was confirmed that pores formed in the porous silicon substrate were very even.

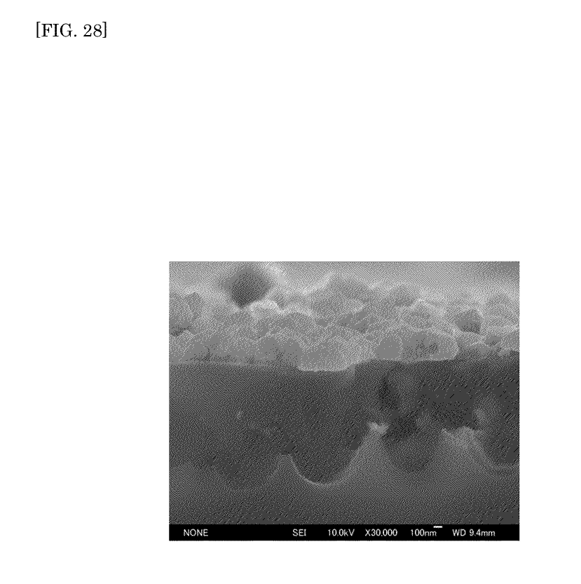

Next, the aforementioned porous silicon substrate as an electrode, and an aqueous solution containing 0.1 M copper sulfate and 0.1 M sulfuric acid as an electrolyte were used, and a current was applied at a constant current density of 6.4 μA/cm² for 30 minutes, to obtain a porous silicon material. The obtained porous silicon material was observed by a scanning electron microscope. The result is shown in FIG. 28.

From the results shown in FIG. 27 and FIG. 28, it can be seen that copper is evenly formed deeply inside pores of the porous silicon material in the porous silicon material to which a hydrophobizing treatment has been conducted obtained in Example 14 as compared with the porous silicon material obtained in Comparative Example 5.

### Example 15

A silicon substrate [length 1 cm×width 1 cm×thickness 600 μm, commercially available from SUMCO CORPORATION, p-type silicon (100), specific resistance 0.01 Ω·cm] was prepared. An ethanol solution containing 22% by weight of hydrogen fluoride was prepared. The silicon substrate as an active electrode and a platinum bar as a counter electrode were used, and a current was applied for 20 minutes at a current density of 2 mA/cm² at room temperature to prepare a porous silicon substrate.

The porous silicon substrate obtained in the above was observed by a scanning electron microscope (commercially available from JEOL Ltd., product number: JSM 6500FE) and a transmission electron microscope (commercially available from JEOL Ltd., Product number: JEM-2200FS), and an average diameter in the planner direction of the porous silicon substrate and a depth along the thickness of the porous silicon substrate were observed for 100 pores. As a result, the average diameter of pores in the planner direction was 3 nm, and the depth along the thickness was 2 μm. Since the maximum value and the minimum value of pore diameters of pores formed in the porous silicon substrate fell within the range of ±2 nm of the average diameter, it was confirmed that pores formed in the porous silicon substrate were very even.

Next, in order to carry out a hydrophobizing treatment on the porous silicon substrate, a 0.1 M methyl propiolate solution in n-hexane was prepared by dissolving methyl propiolate in n-hexane by using methyl propiolate as an organic compound having a carbon-carbon unsaturated triple bond and a hydrophobic group at its terminal.

By dipping the porous silicon substrate obtained above in the 0.1 M methyl propiolate solution in n-hexane in an argon gas atmosphere at room temperature for 15 hours, a hydrophobizing treatment was carried out on the porous silicon substrate. Whether or not the hydrophobizing treatment was carried out on the porous silicon substrate was confirmed by a Fourier transform infrared spectrophotometer (FT-IR). As a result, successful conduction of the hydrophobizing treatment on pore walls of the porous silicon substrate was confirmed.

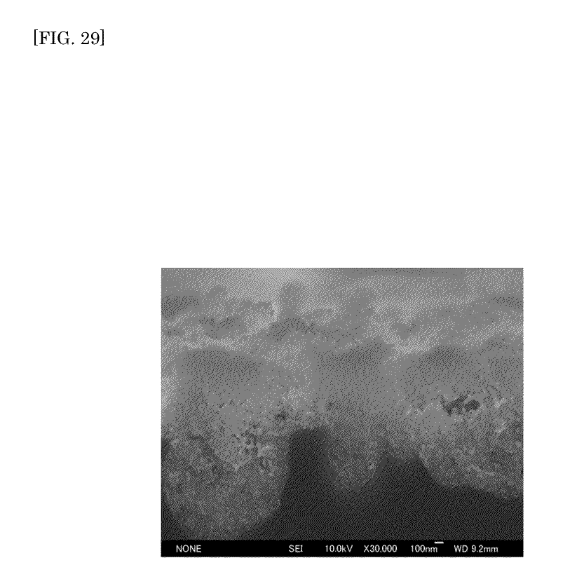

The porous silicon substrate to which a hydrophobizing treatment has been conducted obtained above as an electrode, and an aqueous solution containing 0.1 M zinc sulfate and 0.1 M sulfuric acid as an electrolyte were used, and a current was applied at a constant current density of 6.4 μA/cm² for 30 minutes, to obtain a porous silicon material. The obtained porous silicon material was observed by a scanning electron microscope. The result is shown in FIG. 29. From the result shown in FIG. 29, it can be seen that zinc is evenly formed inside pores of the porous silicon material because the hydrophobizing treatment has been conducted to the porous silicon material obtained in the above.

Next, by clipping the porous silicon material obtained in the above in an aqueous solution containing 25% by weight of tetramethyl ammonium hydroxide at a liquid temperature of 90° C., silicon contained in the porous silicon material was dissolved and particulate metallic nanoparticles were collected.

### Example 16

A silicon substrate [length 1 cm×width 1 cm×thickness 600 μm, commercially available from SUMCO CORPORATION, p-type silicon (100), specific resistance 0.01 Ω·cm] is prepared. An ethanol solution containing 22% by weight of hydrogen fluoride is prepared, and the silicon substrate as an active electrode, and a platinum bar as a counter electrode are used. A current is applied for 20 minutes at a current density of 2 mA/cm² at room temperature, to prepare a porous silicon substrate. This porous silicon substrate is left still in an oven at 80° C. for 1 hour, to remove moisture on the surface and inside pores of the porous silicon substrate, and thus dried.

The dried porous silicon is put into a quartz tube, and nitrogen gas is continuously flown in the quartz tube for 1 hour. Then, instead of the nitrogen gas, a mixed gas containing acetylene gas and nitrogen gas in a volume ratio of 1:1 is continuously flown in the quartz tube for 10 minutes.

Next, the quartz tube is put into an oven at an internal temperature of 500° C. while the mixed gas is flown in the quartz tube, and the quartz tube is retained at a temperature of 500° C. for 9 minutes and 30 seconds, and then nitrogen gas is continuously flown instead of the mixed gas for 30 seconds. Thereafter, the quartz tube is taken out of the oven, and the quartz tube and the porous silicon are allowed to cool to room temperature while nitrogen gas is flown in the quartz tube.

Using the porous silicon substrate to which a hydrophobizing treatment has been conducted obtained in the above as an electrode, and using an aqueous solution containing 0.1 M potassium hexachloroplatinate and 0.5 M sodium chloride as an electrolyte, a current is applied at a constant current density of 6.4 μA/cm² for 30 minutes, to obtain a porous silicon material.

Next, by dipping the porous silicon material obtained in the above in an aqueous solution containing 25% by weight of tetramethyl ammonium hydroxide at a liquid temperature of 90° C., silicon contained in the porous silicon material can be dissolved, and particulate metallic nanoparticles can be taken out.

### INDUSTRIAL APPLICABILITY

The porous silicon material of the present invention is expected to be used, for example, for an electrode for a wet solar cell, an electrode for a fuel cell, and the like. Also, metallic nanoparticles or nanofibers are expected to be used, for example, for an electrode material for a fuel cell or the like, a catalytic material, a biosensing material and the like because they have a high specific surface area.

1-7. (canceled)

8. A method for producing a porous silicon material filled with a metal, comprising the steps of:
carrying out a hydrophobizing treatment on a porous silicon substrate having pores of 1 to 5 nm in pore diameter, and
carrying out an electrodeposition treatment on the porous silicon substrate to precipitate a metal inside the pores of the porous silicon substrate.

9. The method for producing a porous silicon material according to claim 8, wherein the porous silicon substrate having pores of 1 to 5 nm in pore diameter is produced by forming pores in a silicon substrate having a specific resistance of 5 to 20 Ω·cm with the use of hydrogen fluoride.

10. The method for producing a porous silicon material according to claim 8, wherein the hydrophobizing treatment is carried out on the porous silicon substrate by using an organic compound having a carbon-carbon unsaturated double bond or a carbon-carbon unsaturated triple bond, and a hydrophobic group at its terminal.

11. The method for producing a porous silicon material according to claim 9, wherein the hydrophobizing treatment is carried out on the porous silicon substrate by using an organic compound having a carbon-carbon unsaturated double bond or a carbon-carbon unsaturated triple bond, and a hydrophobic group at its terminal.

12. A method for producing a metallic nanoparticle or nanofiber, comprising the steps of:
producing a porous silicon material filled with a metal by the method for producing a porous silicon material according to claim 8, and
dissolving silicon contained in the porous silicon material filled with a metal.

13. A method for producing a metallic nanoparticle or nanofiber, comprising the steps of:
producing a porous silicon material filled with a metal by the method for producing a porous silicon material according to claim 9, and
dissolving silicon contained in the porous silicon material filled with a metal.

14. A method for producing a metallic nanoparticle or nanofiber, comprising the steps of:
producing a porous silicon material filled with a metal by the method for producing a porous silicon material according to claim 10, and
dissolving silicon contained in the porous silicon material filled with a metal.

15. A metallic nanoparticle or a nanofiber obtained by the producing method according to claim 12.

16. A metallic nanoparticle or a nanofiber obtained by the producing method according to claim 13.

17. A metallic nanoparticle or a nanofiber obtained by the producing method according to claim 14.

18. A porous silicon material obtained by the process according to claim 8, wherein said porous silicon material has pores of 1 to 5 nm in pore diameter and a specific resistance of 5 to 20 Ω·cm, and the pores of said porous silicon material are filled with a metal.

19. A porous silicon material obtained by the process according to claim 9, wherein said porous silicon material has pores of 1 to 5 nm in pore diameter and a specific resistance of 5 to 20 Ω·cm, and the pores of said porous silicon material are filled with a metal.

20. A porous silicon material obtained by the process according to claim 10, wherein said porous silicon material has pores of 1 to 5 nm in pore diameter and a specific resistance of 5 to 20 Ω·cm, and the pores of said porous silicon material are filled with a metal.
